(19) United States
(12) Patent Application Publication
(10) Pub. No.: US 2005/0195630 A1
(43) Pub. Date: Sep. 8, 2005

(54) Nonvolatile semiconductor memory device

(76) Inventors: Tsuyoshi Arigane, Tachikawa (JP); Takashi Kobayashi, Tokorozawa (JP); Yoshitaka Sasaga, Tachikawa (JP)

Correspondence Address: Antonelli, Terry, Stout & Kraus, LLP, Suite 1800, 1300 North Seventeenth Street, Arlington, VA, 22209, US

(21) Appl. No.: 11/060,422

(22) Filed: Feb. 18, 2005

(30) Foreign Application Priority Data
Mar. 2, 2004 (JP) 2004-057662

(51) Int. Cl. G11C 7/02

(52) U.S. Cl. 365/53

(57) ABSTRACT

A nonvolatile semiconductor memory device to be manufactured at a high production yield has memory cells disposed in a highly integrated manner by suppressing the occurrence of dislocation typically caused by such highly integrated disposition of the memory cells. In order to achieve is result, each field shielding transistor is formed in a select transistor region having a small isolation width, and 0 V is applied to a gate of the field shielding transistor to isolate each local bit line from the others. The gate of each field shielding transistor is connected to another one with a gate member, so that the layout area is reduced more than when a contact hole is provided directly at the gate of each field shielding transistor.

### CLAIM OF PRIORITY

The present application claims priority from Japanese application JP 2004-057662, filed on Mar. 2, 2004, the content of which is hereby incorporated by reference into this application.

### FIELD OF THE INVENTION

The present invention relates in general to a nonvolatile semiconductor memory device; and, more particularly, the invention relates to a technique to be applied effectively to form highly integrated flash memories and to improve the production yield of the same.

### BACKGROUND OF THE INVENTION

A flash memory is a well-known electrically rewritable nonvolatile semiconductor memory device that enables data to be erased from its memory cells collectively. The flash memory has excellent portability and shock resistance. In recent years, the market for such flash memories has been rapidly expanding, since they are usable as file memory devices in compact portable information devices, such as portable personal computers, digital still cameras, etc.

To expand the market for such flash memories, however, a reduction in the bit cost is very important. Thus, various methods for forming memory cells have been proposed to realize such a reduction in the bit cost.

For example, the official gazette of JP-A 28428/2001 (patent document 1) discloses a flash memory that has memory cells, each being composed of a semiconductor region (that includes both a source diffusion layer 101 and a drain diffusion layer 102) and three gates in each well 119 provided in a semiconductor substrate 100, as shown in FIG. 1. The three gates of a memory cell are a first gate (floating gate) 103, a second gate (control gate) 104, and a third gate (selected gate) 105. The first gate 103 is formed in a gap between two adjacent third gates 105. The first gate 103 and the well 119 are insulated from each other by a first insulator film 106; the first gate 103 and the third gate 105 are insulated from each other by a third insulator film 108; and the first gate 103 and the second gate 104 are insulated from each other by a second insulator film. And, the third gate 105 and the semiconductor substrate 100 are insulated from each other by a fourth insulator film; while, the third gate 105 and the second gate 104 are insulated from each other by a fifth insulator film 110. Each second gate 104 is connected to another in the row direction (right-left direction in FIG. 1) to form word lines. The third gates 105 are extended in the column direction perpendicular to the direction of the word lines. The source diffusion layer 101 and the drain diffusion layer 102 are disposed in a direction perpendicular to the word lines and function as memory cell local bit lines. When information is to be programmed in or read from memory cells, the select transistor is turned on or off to select the object local bit line. The memory cell array of the flash memory disclosed in the patent document 1 is configured as a virtual grounding type array. When information is to be programmed in or read from the memory cells, each memory cell is isolated from the others electrically by the third gate.

The publication “10MB/s Multi-Level Programming of Gb-Scale Flash Memory Enabled by New AG-AND Cell Technology”(Y. Sasago et al., IEDM Technical Digest p.952, 2002) (non-patent document 1) discloses a flash memory having so-called multi-level memory cells. When information is to be programmed in these memory cells, 0 V is applied to the source, 4.5 V is applied to the drain, 13.5 V is applied to the second gate, and 1.4 V is applied to the third gate of each memory cell.

The official gazette of JP-A No. 275800/1994 (patent document 2) discloses a technique related to a NAND type EEPROM in which memory cells provided with a floating gate and a control gate, respectively, are connected serially, and each select transistor region is isolated from the others by a silicon oxide film. FIG. 2 shows a top view of the select transistor region described in this document. A global bit line 117 is connected to an active region 112, to be used as a local bit line, through a contact hole 116. The gate 113 of the select transistor is disposed in two steps in the active region 112. The select transistor is composed of an E (enhancement) type transistor 114 and a D (Depression) type transistor 115, and the transistors 114 and 115 are connected serially. Each local bit line of the select transistor region is isolated from the others by a silicon oxide film 111.

On the other hand, the official gazette of JP-A No.198778/1993 (patent document 3) discloses a technique related to an NOR type nonvolatile semiconductor memory device, such as an EEPROM, a flash memory, or the like. According to this technique, the bit lines are formed with a diffusion layer, and the trench isolation method is used for providing isolation between adjacent memory cells. FIG. 3 shows an A-A′ cross sectional view in FIG. 2 showing a local bit line that is isolated using the trench isolation method. Because the trench isolation method forms isolation trenches in the subject semiconductor substrate using lithography and etching techniques, the isolation width can be reduced more than when the LOCOS method is used. The memory cells can thus be reduced in size.
[Patent document 1] Official gazette of JP-A No. 28428/2001 (corresponding to U.S. Pat. No. 6,438,028)
[Patent document 2] Official gazette of JP-A No. 275800/1994 (corresponding to U.S. Pat. No. 6,151,249)
[Patent document 3] Official gazette of JP-A No. 198778/1993
[Non-patent document 1 ]“10-MB/s Multi-Level Programming of Gb-Scale Flash Memory Enabled by New AG-AND Cell Technology”(Y. Sasago et al., IEDM Technical Digest p.952, 2002)

### SUMMARY OF THE INVENTION

If the shallow groove isolation (SGI) method as disclosed in the patent document 3 is used to form the select transistor regions of a flash memory, however, the following problems arise as the isolation width is narrowed more and more.

(1) In a memory cell forming process, the surface of the isolation trench is oxidized, and the cubic volume of the trench increases during a thermal oxidation treatment performed after the isolation trench is formed. As a result, dislocation might occur due to stress at the boundary between an insulator film and the semiconductor substrate. And, if such dislocation occurs, the select transistor is punched through, with the result that local bit line selection is disabled and the subject memory cells cannot be driven. Both the reliability and the production yield of the flash memory are thus lowered.

(2) If a multi-level memory is composed of memory cells, the threshold value window, when programming/erasing data in/from the memory cells, becomes larger than that in a two-level memory. And, in order to realize the same throughput for programming as that of a two-level memory, the local bit line potential is required to be set larger to speed up the programming operation of those memory cells themselves. This makes it difficult to employ the trench isolation method for isolation.

Under such circumstances, it is an object of the present invention to provide a technique for realizing a highly integrated non-volatile semiconductor memory device.

It is another object of the present invention to provide a technique that can improve the reliability of the nonvolatile semiconductor memory device.

The above and further objects and novel features of the present invention will more fully appear from the following detailed description when the same is read in conjunction with the accompanying drawings.

A typical one of the aspects of the present invention to be disclosed in this specification will be summarized as follows.

The nonvolatile semiconductor memory device of the present invention includes a plurality of memory cells disposed in the form of a matrix on a semiconductor substrate, a plurality of select transistors having a function to select the row or column direction of the plurality of memory cells, and a peripheral circuit for driving the plurality of memory cells and each select transistor. Each select transistor is isolated from the others by a field shielding transistor.

The effects to be obtained by a typical one of the aspects of the present invention disclosed in this specification will be described briefly as follows.

Each select transistor is isolated from the others by a field shielding transistor, thereby the occurrence of dislocation in the select transistor is suppressed. This is why a high production yield is realized for the nonvolatile semiconductor memory device, even when the memory cells are disposed in a highly integrated, manner by reducing the pitch of the bit lines.

### BRIEF DESCRIPTION OF THE DRAWINGS

FIG. 1 is a cross sectional view of memory cells of a conventional nonvolatile semiconductor memory device;

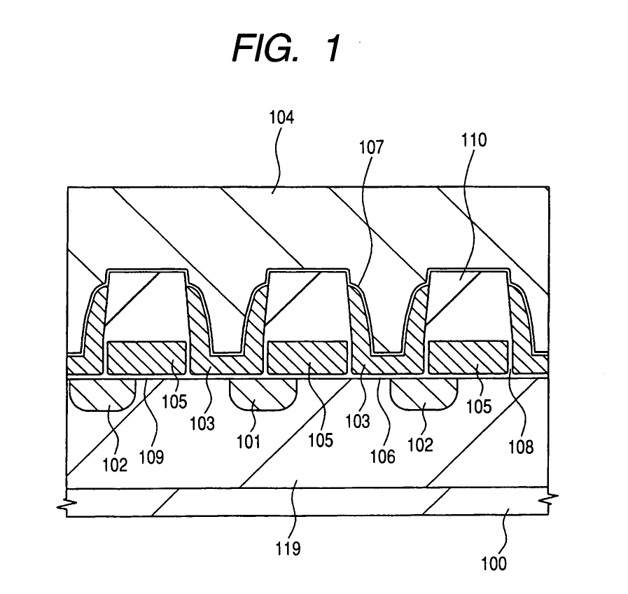

FIG. 2 is a top view of a select transistor region of the conventional nonvolatile semiconductor memory device;

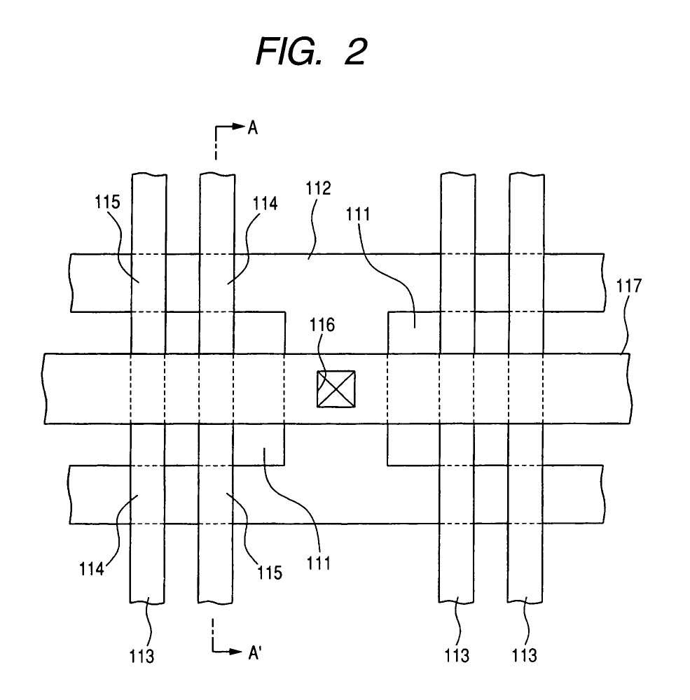

FIG. 3 is a cross section view taken at the line A-A′ in FIG. 2;

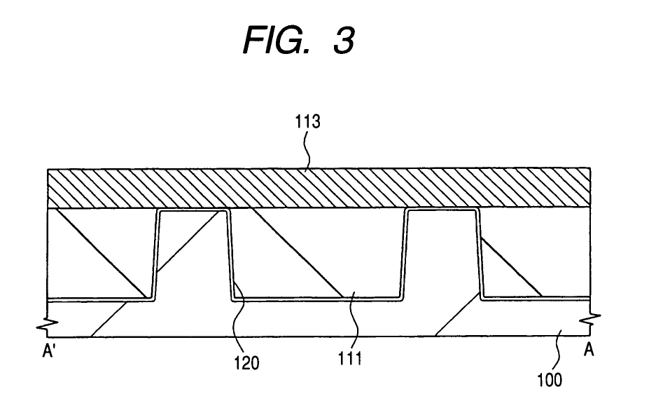

FIG. 4 is a top view of a major portion of a region that includes a select transistor and a peripheral circuit of a flash memory in an embodiment of the present invention;

FIG. 5 is a cross sectional view taken at the line A-A′ in FIG. 4;

FIG. 6 is a cross sectional view taken at the line B-B′ in FIG. 4;

FIG. 7 is a cross sectional view taken at the line C-C′ in FIG. 4;

FIG. 8 is a top view of a major portion of a flash memory representing an embodiment of the present invention;

FIG. 9 is a cross sectional view taken at the line A-A′ in FIG. 8;

FIG. 10 is a cross sectional view taken at the line B-B′ in FIG. 8;

FIG. 11 is a cross sectional view taken at the line C-C′ in FIG. 8;

FIG. 12 is a partial circuit diagram denoting the voltage application when programming data in a flash memory according to an embodiment of the present invention;

FIG. 13 is a partial circuit diagram for denoting voltage application when reading data from a flash memory according to an embodiment of the present invention;

FIG. 14 is a partial circuit diagram for denoting voltage application when erasing data from a flash memory according to an embodiment of the present invention;

FIG. 15 is a cross sectional view of a flash memory according to an embodiment of the present invention with respect to a method of manufacture of the same;

FIG. 16 is a cross sectional view for denoting how to manufacture the flash memory in a process following that shown in FIG. 15;

FIG. 17 is a cross sectional view for denoting how to manufacture the flash memory in a process following that shown in FIG. 16;

FIG. 18 is a cross sectional view for denoting how to manufacture the flash memory in a process following that shown in FIG. 17;

FIG. 19 is a cross sectional view for denoting how to manufacture the flash memory in a process following that shown in FIG. 18;

FIG. 20 is a cross sectional view for denoting how to manufacture the flash memory in a process following that shown in FIG. 19;

FIG. 21 is a cross sectional view for denoting how to manufacture the flash memory in a process following that shown in FIG. 20;

FIG. 22 is a cross sectional view for denoting how to manufacture the flash memory in a process following that shown in FIG. 21;

FIG. 23 is a cross sectional view taken at the line B-B′ in FIG. 22;

FIG. 24 is a top view denoting a positional relationship among the polysilicon film, the resist shown in FIG. 21, and the resist shown in FIG. 20;

FIG. 25 is a cross sectional view denoting how to manufacture the flash memory in a process following that shown in FIG. 22;

FIG. 26 is a cross sectional view for denoting how to manufacture the flash memory in a process following that shown in FIG. 25;

FIG. 27 is a diagram which illustrates how the isolation characteristics of a field shield transistor depends on the gate length;

FIG. 28 is a cross sectional view for denoting how to manufacture a flash memory according to another embodiment of the present invention;

FIG. 29 is a cross sectional view for denoting how to manufacture the flash memory in a process following that shown in FIG. 28;

FIG. 30 is a cross sectional view for denoting how to manufacture the flash memory in a process following that shown in FIG. 29;

FIG. 31 is a cross sectional view for denoting how to manufacture the flash memory in a process following that shown in FIG. 30;

FIG. 32 is a cross sectional view for denoting how to manufacture the flash memory in a process following that shown in FIG. 31; and

FIG. 33 is a cross sectional view for denoting how to manufacture the flash memory in a process following that shown in FIG. 32.

### DETAILED DESCRIPTION OF THE PREFERRED EMBODIMENTS

Hereunder, the preferred embodiments of the present invention will be described in detail with reference to the accompanying drawings. In the accompanying drawings, the same reference numerals/symbols will be used for the same functional members, and a redundant description thereof will be omitted.

First Embodiment

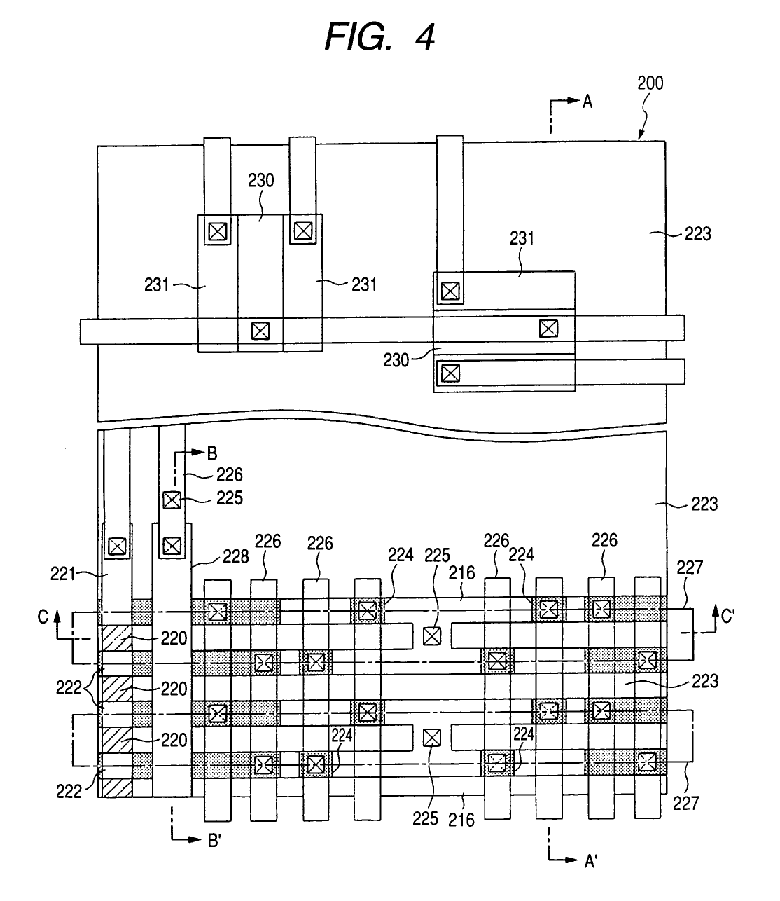

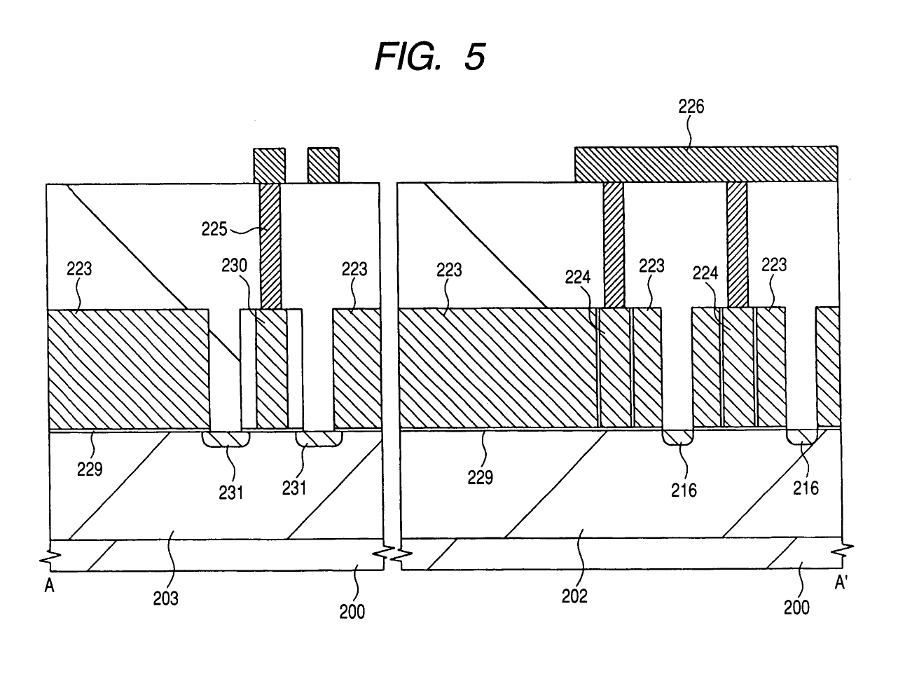

FIG. 4 shows a partial top view of a semiconductor substrate of a nonvolatile semiconductor memory device in accordance with the first embodiment. FIGS. 5 through 7 show cross sectional views of the semiconductor substrate along the line A-A′, the line B-B′, and the line C-C′in FIG. 4, respectively.

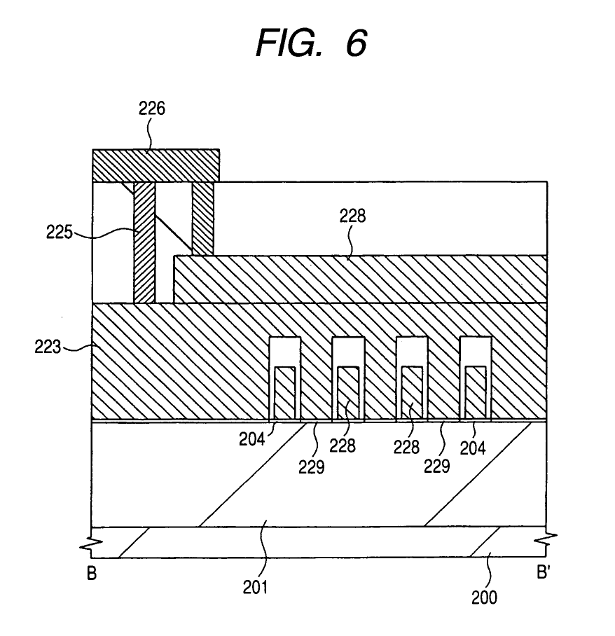

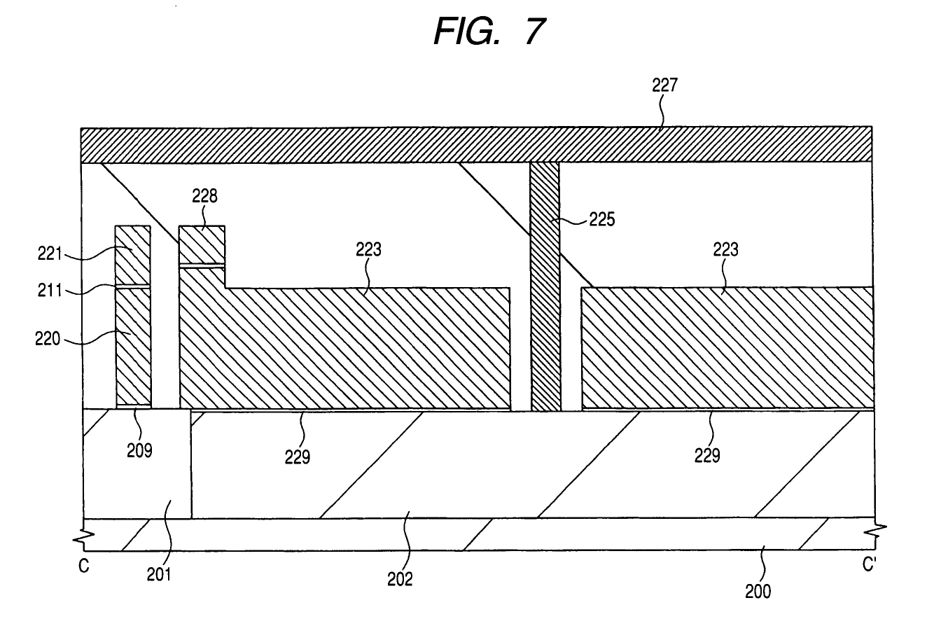

The nonvolatile semiconductor memory device in this first embodiment has memory cells of a so-called flash memory. In the select transistor region adjacent to each memory cell region, a gate 223 of a field shielding transistor is formed. Between the gates 223 of adjacent field shielding transistors, a gate 224 of a select transistor is disposed in two steps so as to correspond to each transistor. The two steps of the gate 224 are connected to each other by a wiring 226 through a contact hole 225 (FIGS. 4 and 5). The gate 223 of each field shielding transistor is insulated from both of the first conductive type first semiconductor region (well) 201 and the first conductive type second semiconductor region (well) 202, formed in the semiconductor substrate 200, respectively, by a fifth insulator film 229 (FIGS. 4 and 7). Each field shielding transistor gate 223 is connected to another under a control gate 228, which is provided at the tip of the subject memory cell region and is connected to the wiring 226 through the contact hole 225 (FIGS. 4 and 6).

A diffusion layer (source/drain) 216 is formed between the gate 223 each field shielding transistor and the gate 224 of each select transistor, and it functions as a memory cell local data line. Each local data line is connected to a global bit line 227 through a contact hole 225 (FIG. 7). Each transistor formed in the peripheral circuit region, except for the gate 230 and the diffusion layer (for both source and drain), is isolated from the others by the gate 223 of the field shielding transistor.

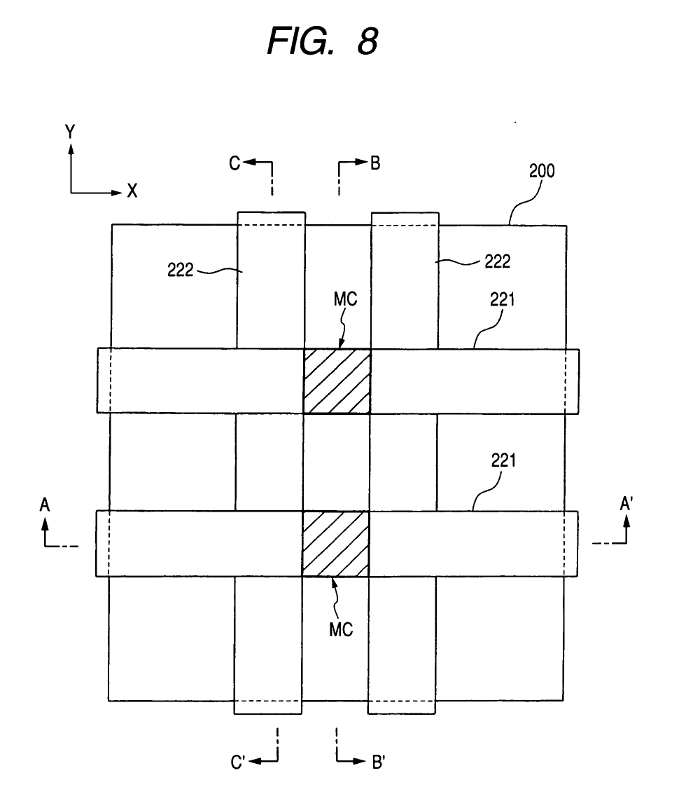

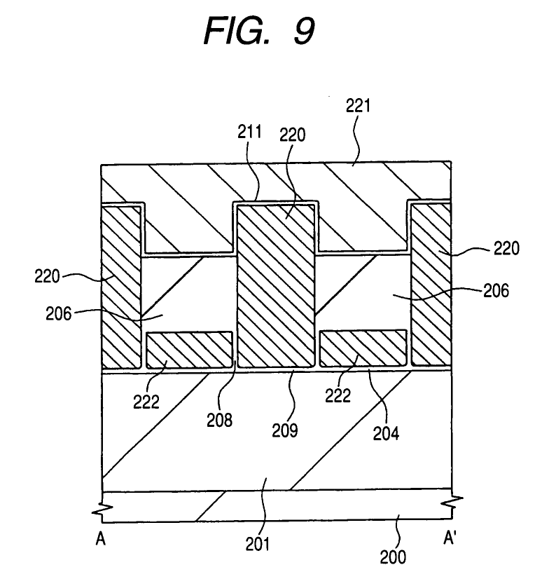

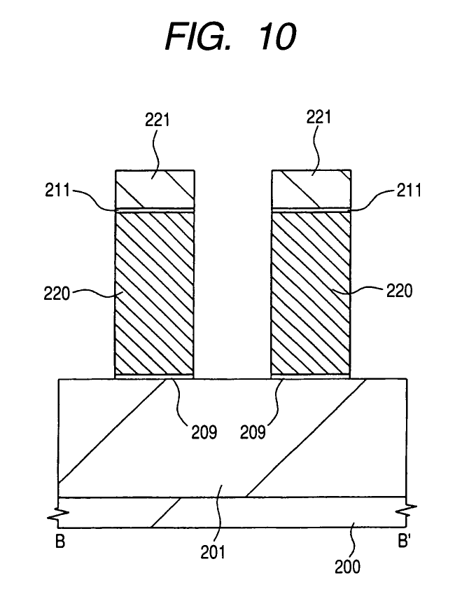

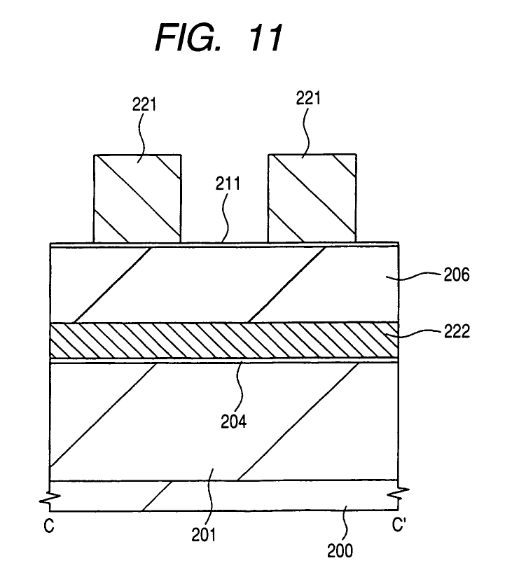

FIG. 8 shows a partial top view of a memory cell region and FIGS. 9 through 11 show cross sectional views of a semiconductor substrate taken along the line A-A′, the line B-B′, and the line C-C′ in FIG. 8. Some members of the semiconductor substrate are omitted in FIG. 8 to make it easier to understand the drawing.

Each memory cell in this first embodiment is composed of a first conductive type (for example, p-type) first semiconductor region 201 to be used as a well, a first gate (floating gate) 220, a second gate (control gate) 221, and a third gate (selected gate) 222. The first gate 220 is formed between two adjacent third gates 222. The first gate 220 and the first conductive type first semiconductor region 201 are insulated from each other by a first insulator film 209 (tunnel oxide film), while the first gate 220 and the second gate 221 are insulated from each other by a second insulator film 211 (interpoly dielectric film). And, the first gate 220 and the third gate 222 are insulated from each other by a third insulator film 208, while the third gate 222 and the, first conductive type first semiconductor region 201 are insulated from each other by a fourth insulator film 204. Furthermore, the second gate 221 and the third gate 222 are insulated from each other by a silicon nitride film 206 and a second insulator film 211. The second gates 221 are connected serially in the row direction to form word lines. The third gates 222 are extended in the column direction perpendicular to the word lines.

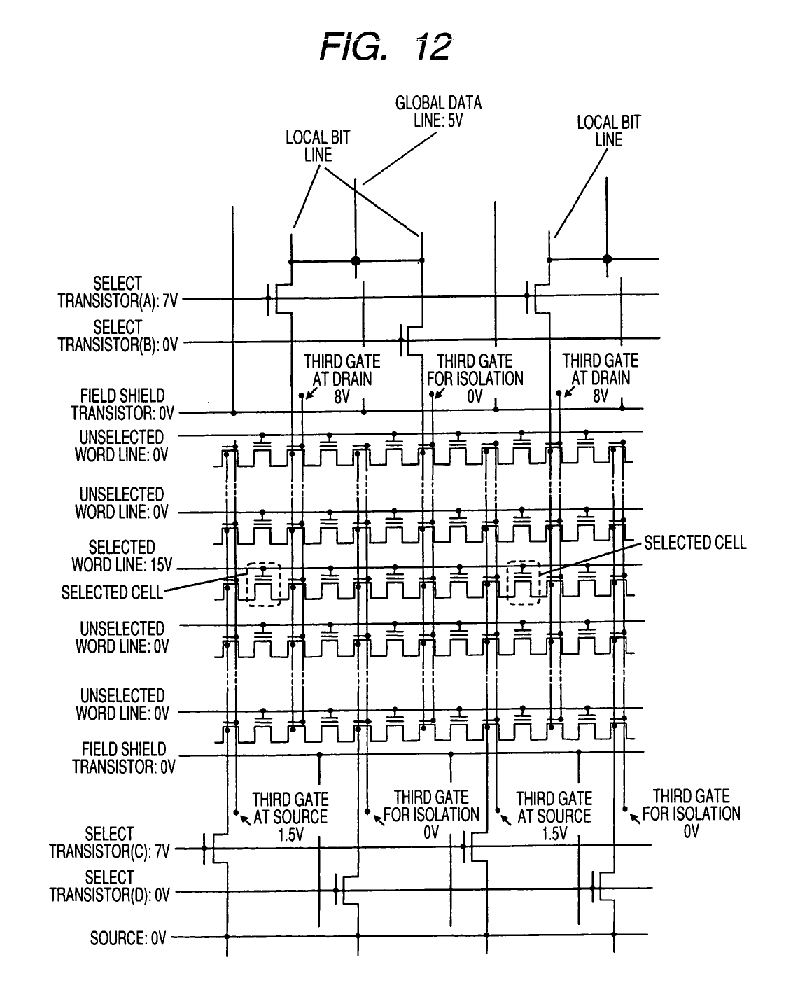

Table 1 shows an example of voltages to be applied for programming/reading/erasing information in/from memory cells in this first embodiment. Hereinafter, the programming/reading/erasing operation of those memory cells will be described with reference to FIGS. 12 through 14.

TABLE 1

| | Global | | | | | | Selected | Third gate | | |
|---|---|---|---|---|---|---|---|---|---|---|
| | bit | Source | Select transistor | | | | word | At | At | Field |
| | line | line | (A) | (B) | (C) | (D) | line | source | drain | shield |
| Programming | 5 V | 0 V | 7 V | 0 V | 0 V | 0 V | 15 V | 1.5 V | 8 V | 0 V |
| Reading | 0 V | 1 V | 7 V | 0 V | 0 V | 0 V | Vread | 3.5 V | 3.5 V | 0 V |
| Erasing | 0 V | 0 V | 0 V | 0 V | 0 V | 0 V | −18 V | 0 V | 0 V | 0 V |

When programming data in a selected memory cell, 5 V is applied to the global bit line, 0 V is applied to the source line, 7 V is applied to the select transistors (A) and (C), 0 V is applied to the select transistors (B) and (D), 15 V is applied to the selected word line, 1.5 V is applied to the third gate at the source, and 8 V is applied to the third gate at the drain, as shown in FIG. 12. At that time, 0 V is applied to the field shielding transistor so as to isolate the local bit line of the select transistor region. This voltage (0 V) generates a strong electric field in the channel of the source diffusion layer located under the first gate, and then it generates hot electrons there, so that the threshold value of the memory cell rises when electrons are injected into the first gate (source side injection hot electron programming method).

In the circuit configuration shown in FIG. 12, data can be programmed in every fourth memory cell among those connected to the same word line in parallel, so that the programming throughput is improved. At that time, two third gates are used for the isolation between selected memory cells connected to the selected word line.

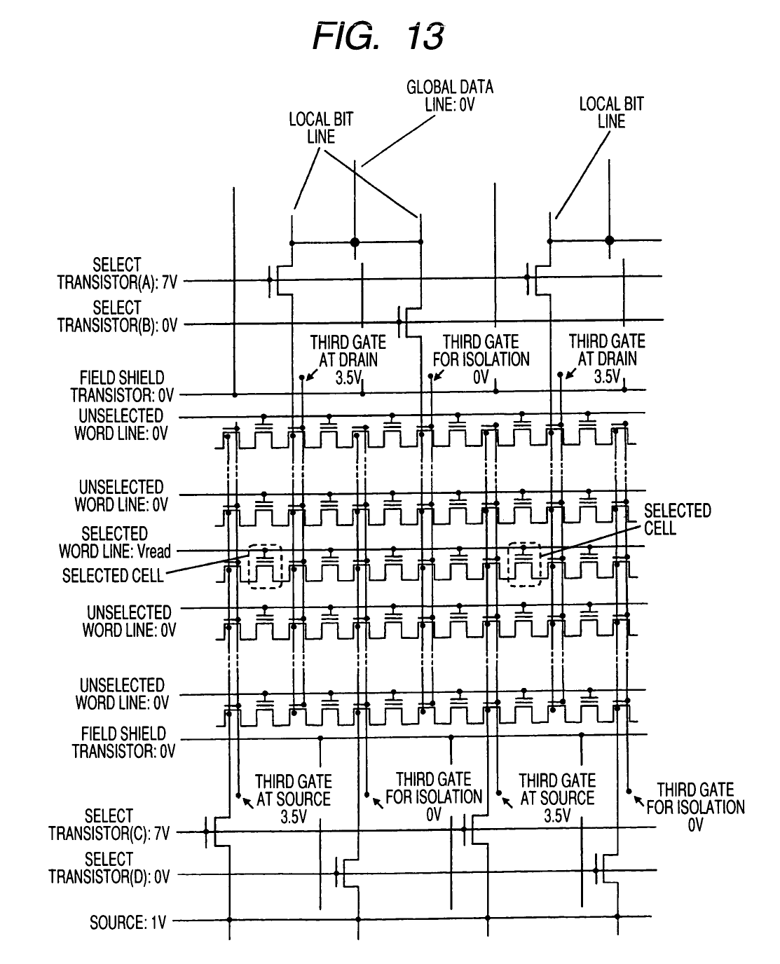

When reading data from a selected memory cell, 0 V is applied to the global bit line, 1 V is applied to the source line, 7 V is applied to the select transistors (A) and (C), 0 V is applied to the select transistors (B) and (D), 0 V is applied to the field shielding transistor, 3.5 V is applied to the third gate at the source, and 3.5 V is applied to the third gate at the drain as shown in FIG. 13, to determine the threshold value of the memory cell. At that time, two third gates are used for the isolation between selected memory cells that are connected to the selected word line.

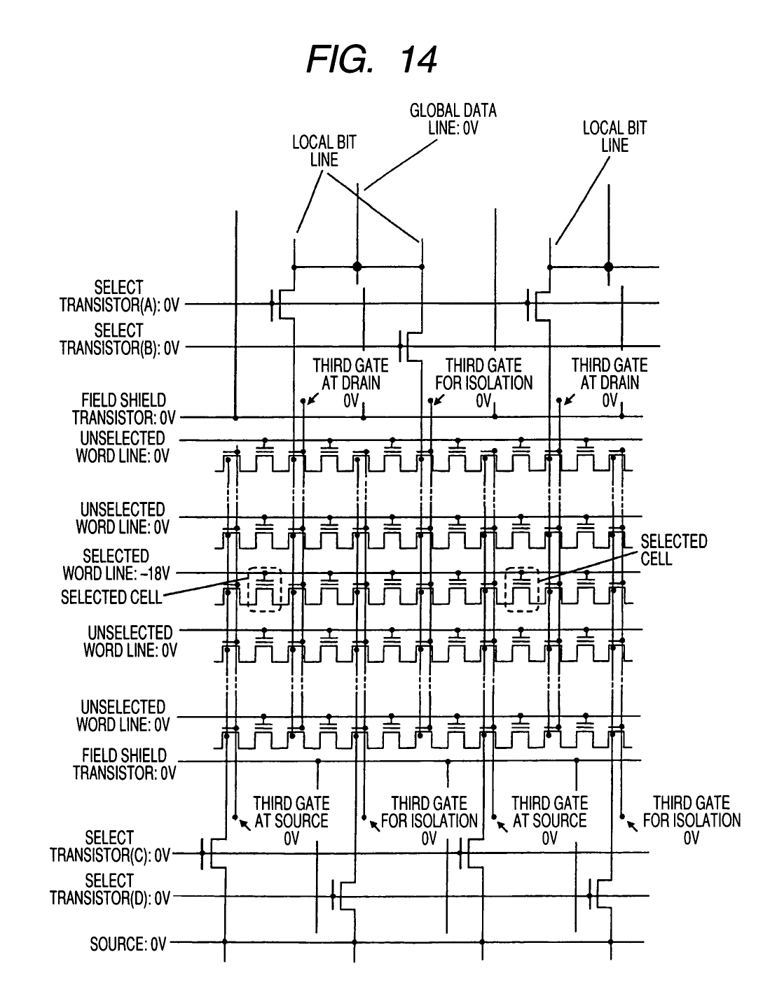

When erasing data from a selected memory cell, 0 V is applied to the global bit line, 0 V is applied to the source line, 0 V is applied to the select transistors (A) to (D), 18 V is applied to the selected word line, 0 V is applied to the third gate at the source and the third gate at the drain, and 0 V is applied to the field shielding transistor, as shown in FIG. 14. As a result, well electrons are discharged from the first gate, thereby the threshold value of the memory cell goes down.

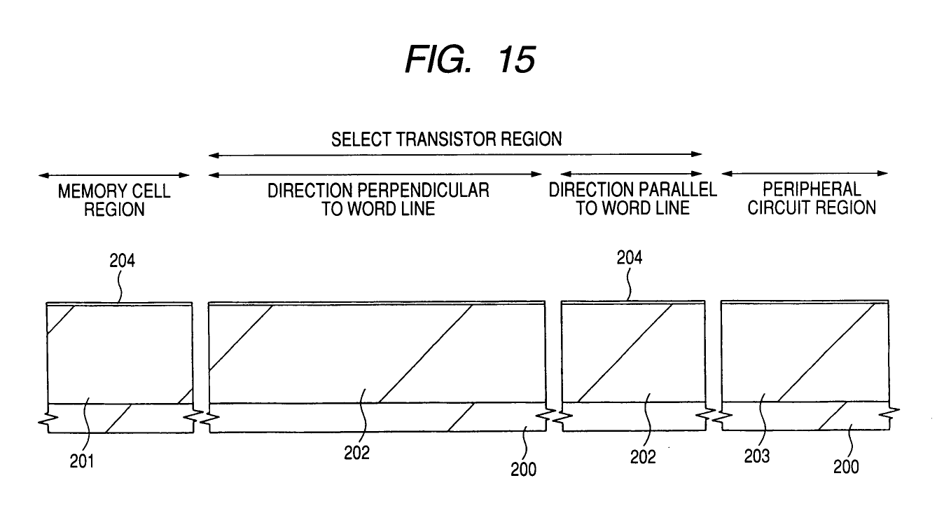

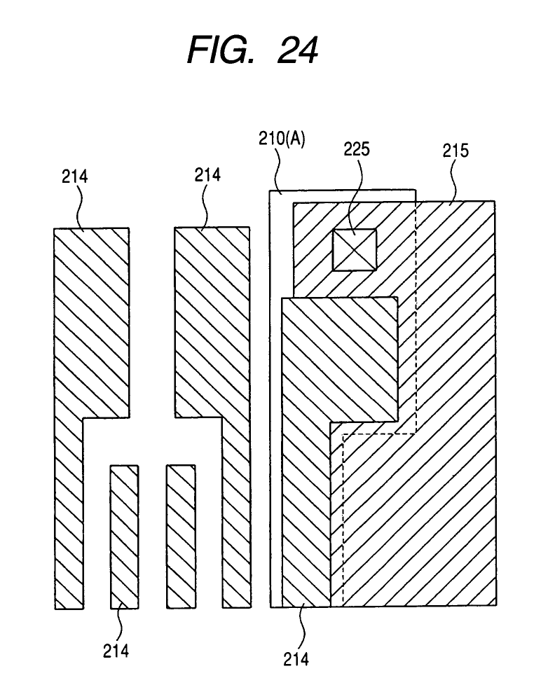

FIGS. 15 through 26 are partial cross sectional and top views of the semiconductor substrate manufactured according to the method of manufacture of the nonvolatile semiconductor memory device in this first embodiment. The subject matter of the drawings (FIGS. 15 through 26) will be divided into a discussion of a memory cell region, a select transistor region, and a peripheral circuit region in the following description.

Initially, first, second, and third conductive type first semiconductor regions 201, 202, and 203, which are assumed to be p-type wells, are formed on a semiconductor substrate 200, then a fourth insulator film 204 is formed on the semiconductor substrate 200 using a thermal oxidation method (FIG. 15). The film 204 is used to insulate a selected gate to be formed later and the substrate 200.

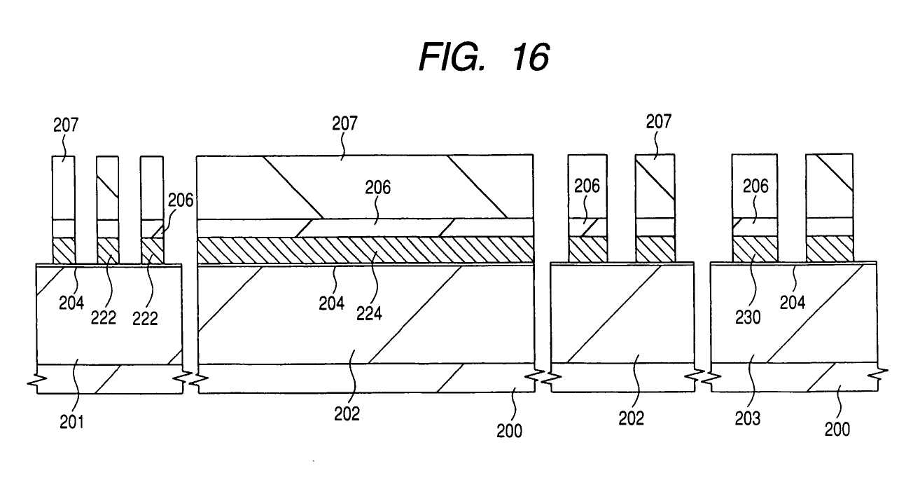

Next, a polysilicon film, which is assumed a selected gate, a to be silicon nitride film 206 for insulating the selected gate, as well as a control gate to be formed later, and a silicon oxide film 207 are deposited on the object surface consecutively using the CVD (Chemical Vapor Deposition) method; and then, those films are patterned using lithography and dry-etching techniques to form the selected gate 222 in the memory cell region, the gate 224 in the select transistor region, and the gate 230 in the peripheral circuit region (FIG. 16).

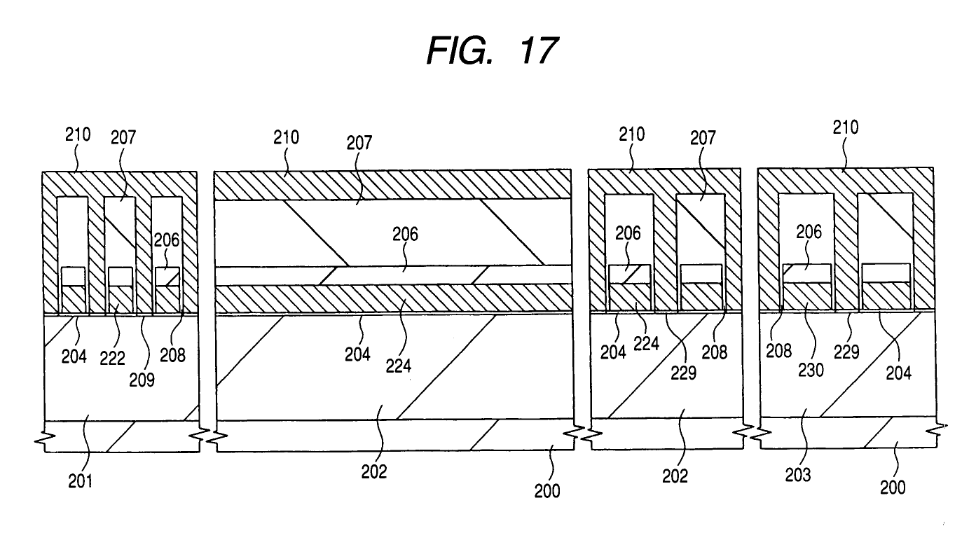

After that, a third insulator film 208 is deposited on the object surface using a CVD method. The film 208 is a silicon oxide film for insulating the selected gate 222, as well as a floating gate to be formed later. Then, a side wall is formed with the third insulator film 208 at the side wall of the selected gate 222 using an etching technique. After that, a first insulator film 209 for insulating the floating gate and the semiconductor substrate 200, as well as a fifth insulator film of the select transistor region and the peripheral circuit region, are formed using thermal oxidation method. After that, a polysilicon film 210, which is assumed to be a floating gate and a field shielding transistor gate is deposited on the object surface (FIG. 17).

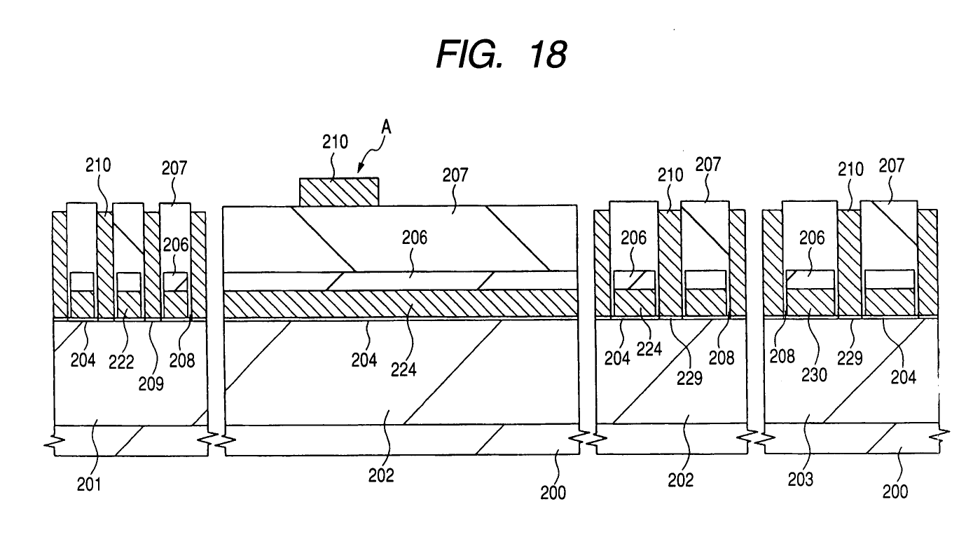

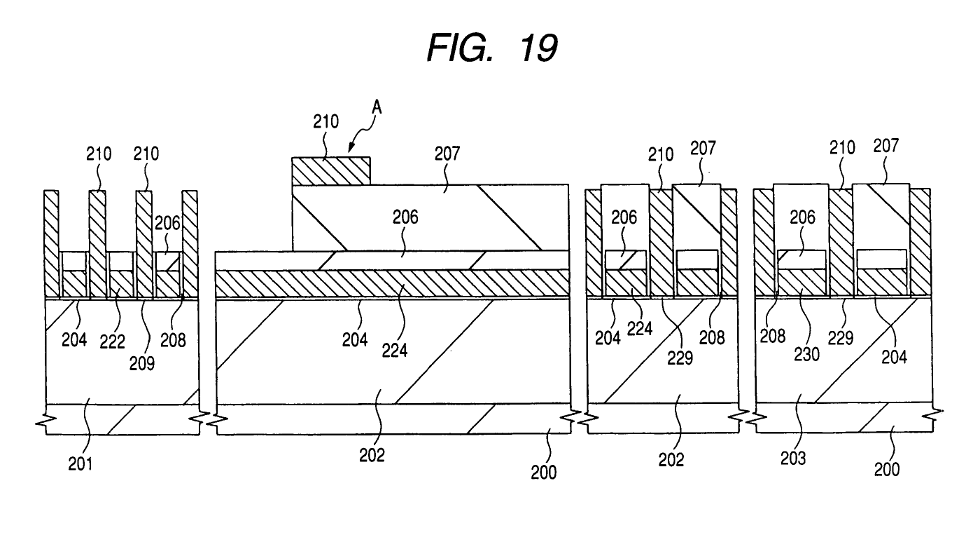

After that, the polysilicon film 210 is etched back until the silicon oxide film 207 is exposed therefrom (FIG. 18), while the film 210, which is assumed to be a field shielding transistor gate connection part later, is left over (FIG. 18A). Then, the silicon oxide film 207 is etched (FIG. 19) and the film 207 is located closer to the memory cell region than the field shielding transistor gate connection part.

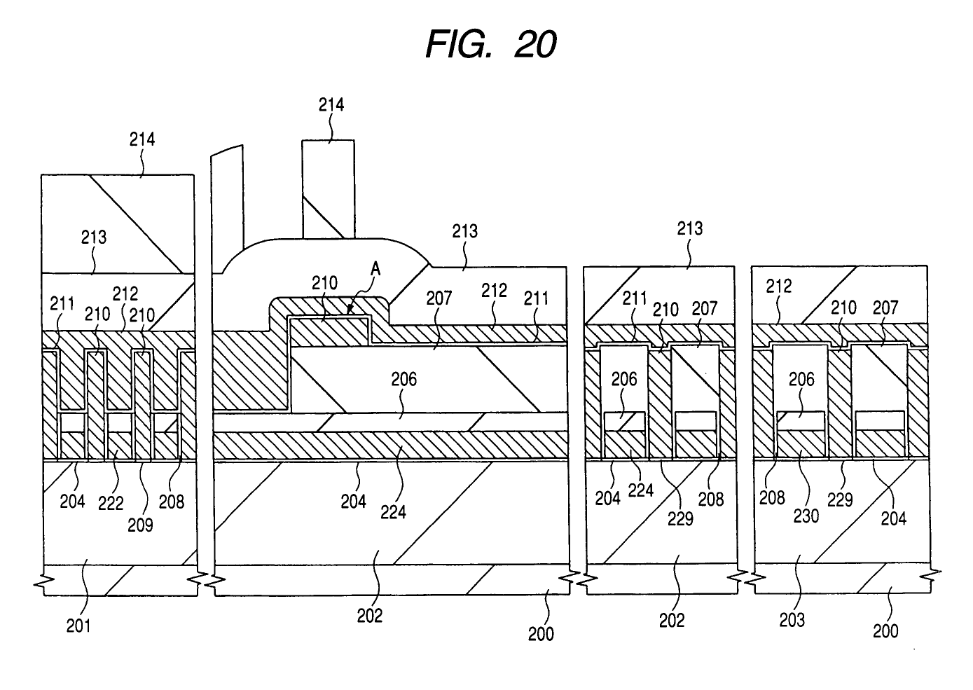

After that, a second insulator film 211 is deposited on the object surface. The film 211 consists of a silicon oxide film, a silicon nitride film, and a silicon oxide film, and it insulates the floating gate (polysilicon film 210) and the control gate. Then, a polysilicon film 212, which is assumed to be a control gate, as well as a silicon oxide film 213, are deposited in the upper portion of the second insulator film 211, and then a resist film 214 is formed on the silicon oxide film 213 to pattern the control gate (word line) (FIG. 20).

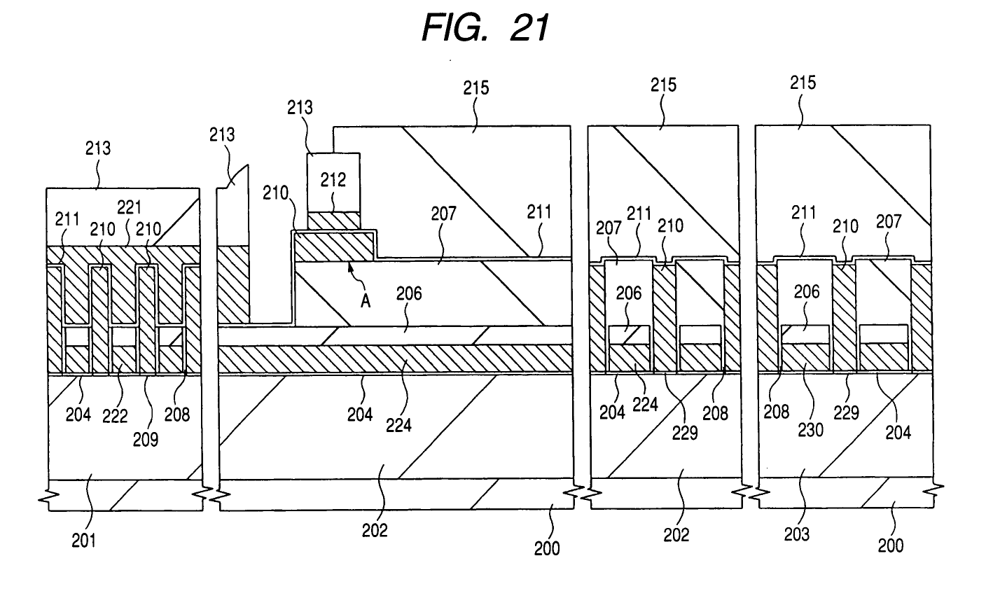

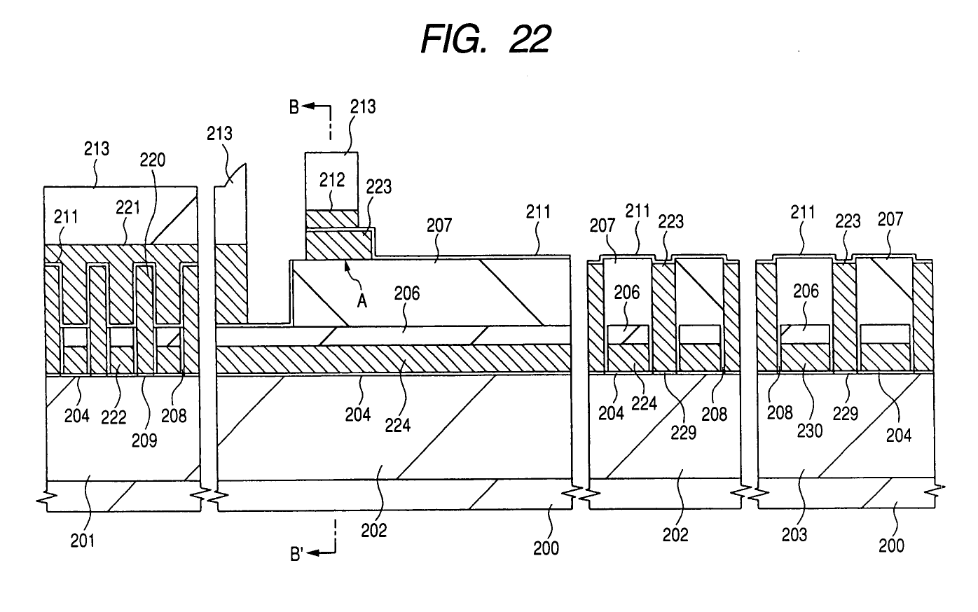

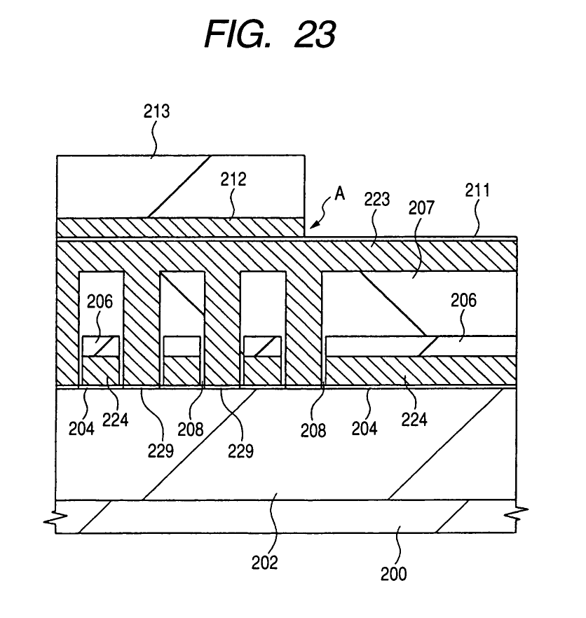

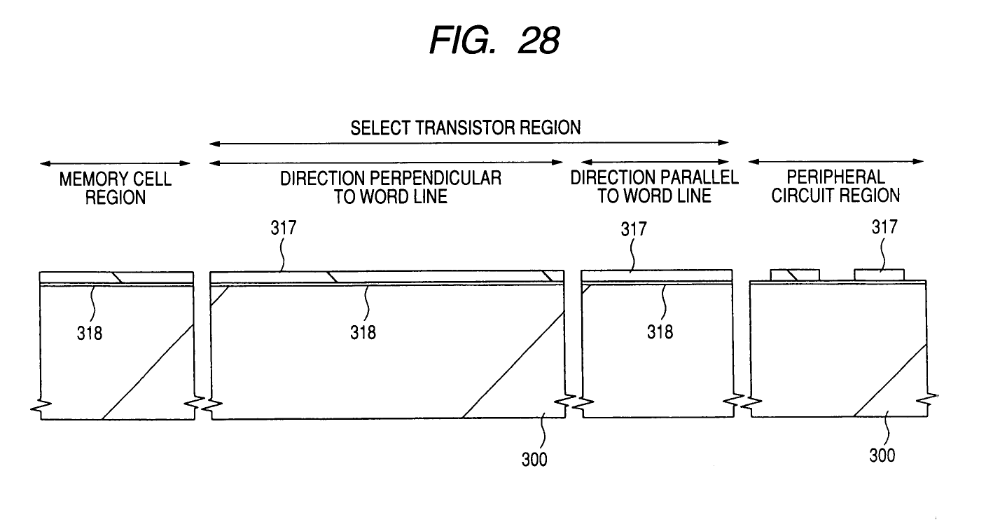

After that, the silicon oxide film 213 and the polysilicon film 212 are etched using the resist 214 as a mask to form the control gate (word line) 221, then the polysilicon film 210 of the select transistor region and the peripheral circuit region are covered with resist 215 so as not to be etched (FIG. 21), and then the polysilicon film 210 of the memory cell region is etched to form the floating gate 220 (FIG. 22). At that time, the polysilicon film 210 for the select transistor region and the peripheral circuit region comes to function as a field shielding transistor gate 223. FIG. 23 shows a cross-sectional view taken at the line B-B′ in FIG. 22. Each field shielding transistor gate 223 is connected to another one with a connection part (A). FIG. 28 shows a top view for denoting a positional relationship among the polysilicon film 210, the resist 215 shown in FIG. 21, and the resist 214 shown in FIG. 20. And, a contact hole 225 is disposed in a region where the polysilicon film 210, which is assumed to be a connection part (A), and the resist 215 are put in layers, thereby power can be supplied to all of the gates 223 of the field shielding transistors at one time.

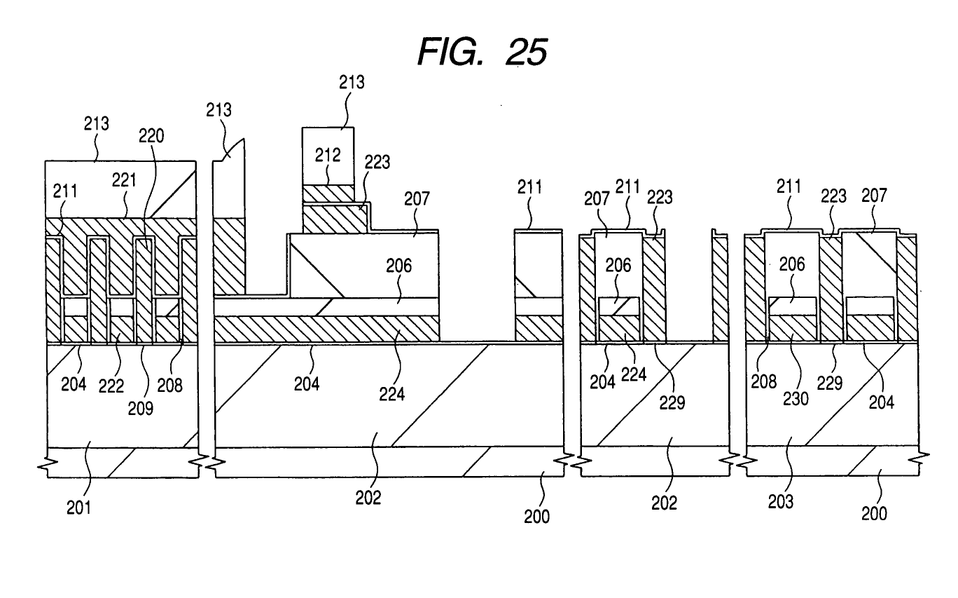

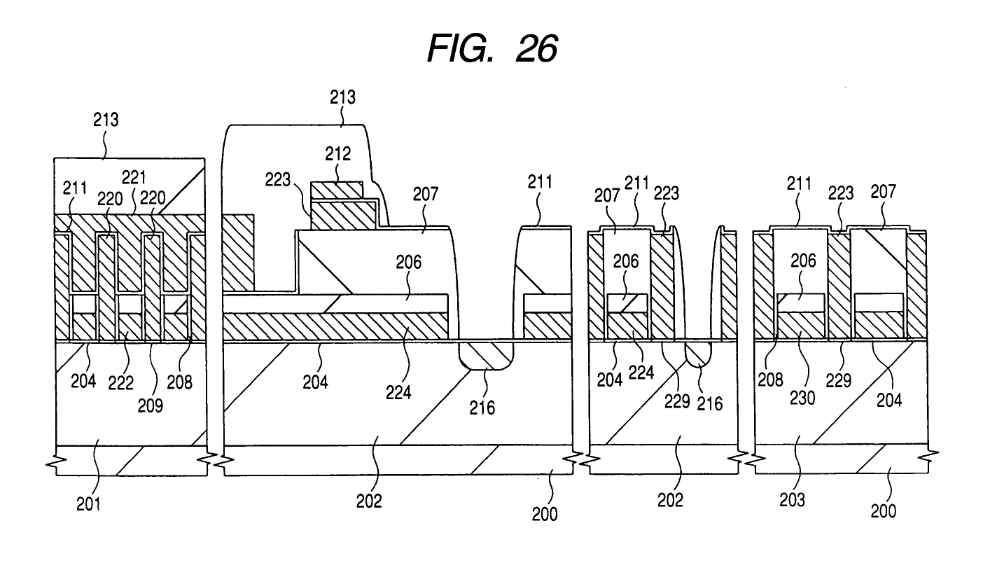

After that, the silicon oxide film 207, the silicon nitride film 206, and the selected gate 222 are etched using lithography and etching techniques. A selected gate 222 is thus isolated for each memory cell (FIG. 25). Then, the diffusion layer (source/drain) 216 of each transistor of the selected gate 222 and the peripheral circuit is formed (FIG. 26).

After that, an interpoly dielectric film is formed in the upper portion of each of the memory cell, the select transistor, and the peripheral MOS (although not illustrated here), and then the interpoly dielectric film is etched to form contact holes for the electrical connection among the control gate 221, the selected gate 222, the diffusion layer (source and drain) 216, the field shielding transistor gate 223, and the peripheral MOS. After that, a metallic film is deposited on the interpoly dielectric film, and then it is patterned to form a wiring. This completes the nonvolatile semiconductor memory device.

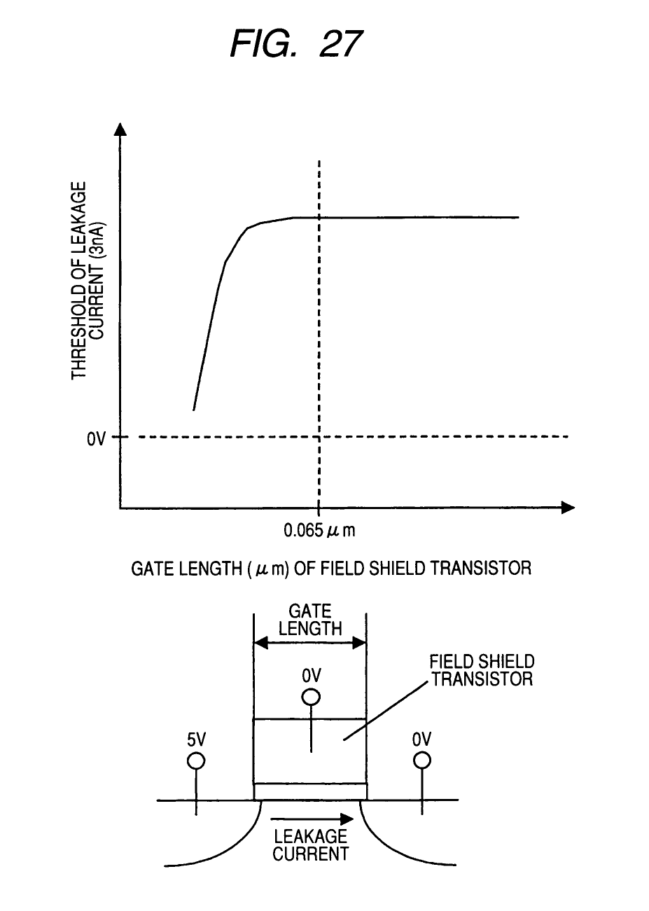

FIG. 27 shows the isolating characteristics of each field shielding transistor of the nonvolatile semiconductor memory device manufactured in accordance with the above-described processes. It is assumed here that the channel current for programming data in memory cells is 30 nA and an allowable leakage current is 3 nA. As shown in FIG. 27, the threshold value of the field shielding transistor in which a 2 nA current flows is understood to be over 0 V. This is why the field shielding transistor can have favorable isolation characteristics when 0 V is applied to the transistor gate. In this embodiment, if a negative bias is applied to the field shielding transistor gate, the transistor's isolation characteristics are further improved. The field shielding transistor can thus be used favorably for multi-level memories.

Furthermore, in this embodiment, such a field shielding transistor is used to isolate each select transistor from the others. Consequently, generation of a stress that occurs in the SGI (isolation trench) structure can be prevented, thereby any dislocation occurrence is suppressed. This is why this embodiment can realize the above-described flash memory at a high production yield, even when the bit line pitch is reduced to realize highly integrated disposition of memory cells in the memory.

Furthermore, according to the manufacturing method of this embodiment, in a flash memory having memory cells, each of which has a floating gate, a control gate, and a selected gate, each field shielding transistor is connected to another one under the control gate located at the edge of the memory cell region, and this can eliminate the need to form a contact hole for each field shielding transistor gate. Consequently, although not illustrated here, the layout area can be reduced more than when each field shielding transistor gate is connected to another with wiring through a contact hole. The memory cells can thus be disposed in a highly integrated manner in the flash memory.

As described above, according to the present invention, each transistor of the flash memory is isolated from the others electrically by a field shielding transistor, so that the possibility of any occurrence of dislocation can be reduced and the production yield of the flash memory can be improved, even when the memory cells are disposed in a highly integrated manner by reducing the bit line pitch. Second Embodiment

FIGS. 28 through 33 show partial cross sectional views of a flash memory to illustrate how to manufacture the same in this second embodiment. This second embodiment differs from the first embodiment only in that each of only the select transistors having a small isolation width is isolated from the others with the use of a field shielding transistor provided in the peripheral circuit. In other regions, isolation trenches are used for such isolation.

At first, a silicon oxide film 318 is formed on a semiconductor substrate 300, and then a silicon nitride film 317 is deposited on the film 318, and the film 317 in the isolation region is removed using lithography and etching techniques (FIG. 28). At that time, no isolation trench is formed in any region where the silicon nitride film 317 is left over, so that an isolation trench or field shielding transistor can be formed selectively using a lithography technique.

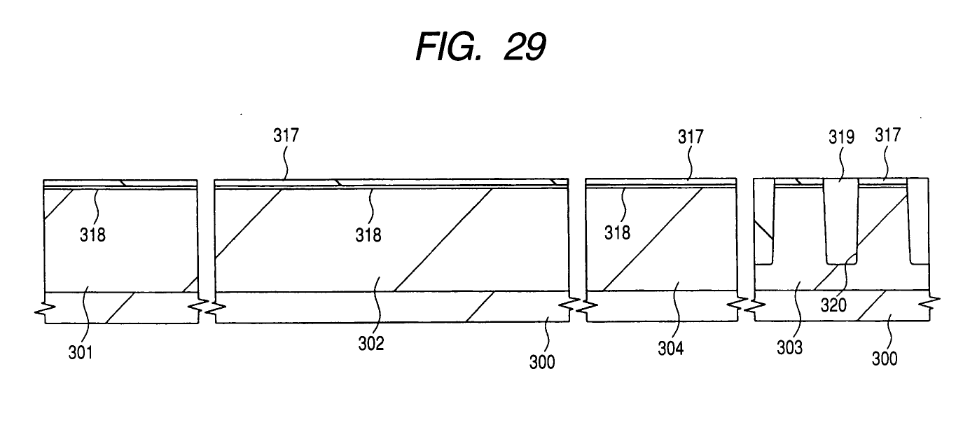

After that, the silicon oxide film 318 and the semiconductor substrate 300 are etched to form a trench for isolation, and then a silicon oxide film 319 is deposited on the semiconductor substrate 300. After that, the film 319 is polished using a CMP (Chemical Mechanical Polishing) method to form an isolation trench 320. After that, first, second, and third semiconductor regions 301, 302, and 303, to be used as p-type wells, are formed (FIG. 29).

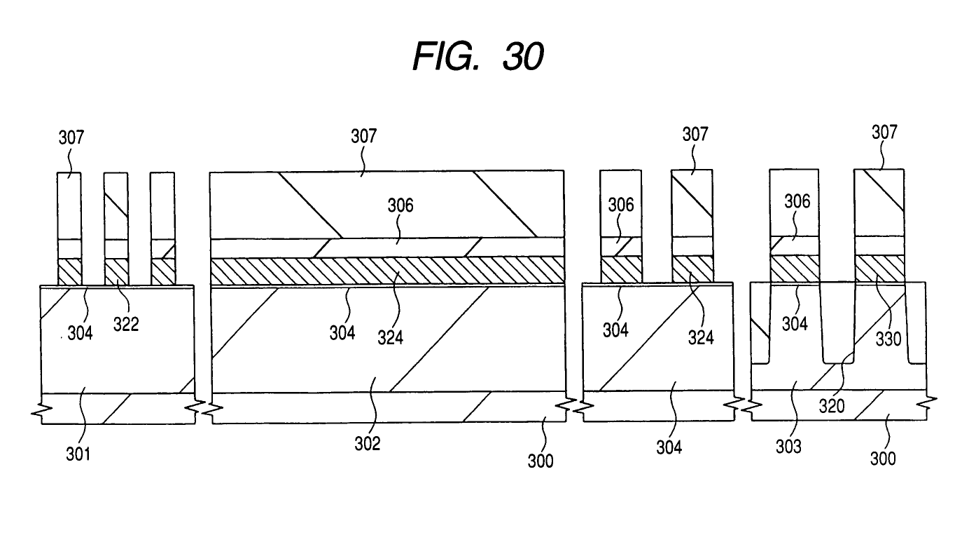

After that, the silicon nitride film 317 and the silicon oxide film 318 are removed in a wet-etching process, and then a silicon oxide film for insulating the selected gate and the semiconductor substrate 300 are formed as a fourth insulator film 304 on the substrate 300 using a thermal oxidation method. After that, a polysilicon film, which is assumed to be a selected gate, as well as a silicon nitride film 306 and a silicon oxide film 307 for insulating the selected gate and the control gate are deposited on the fourth insulator film 304 using a CVD method. Those films are then patterned using both lithography and dry-etching techniques to form the select gate 322 and the gates 324 and 330 (FIG. 30).

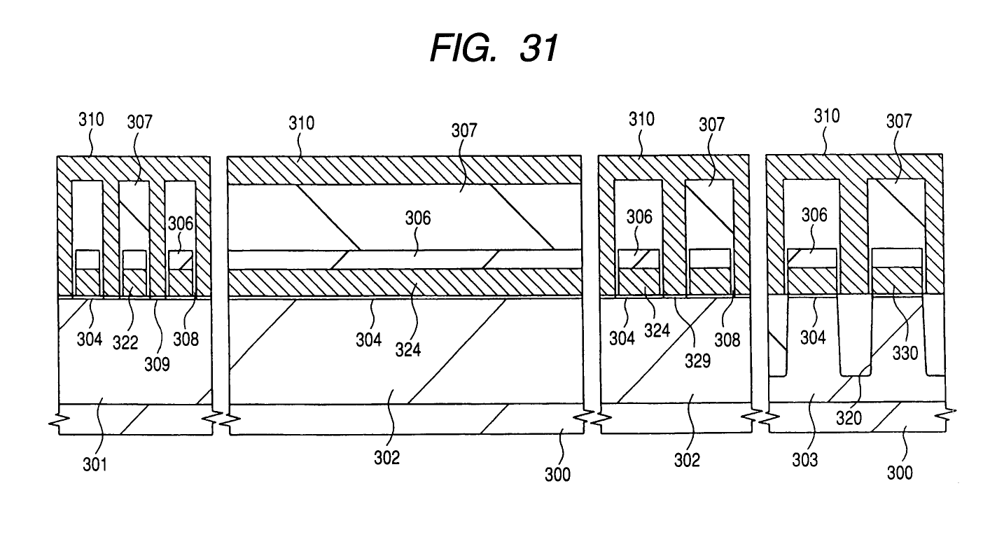

After that, a silicon oxide film for insulating the select gate 322 and the floating gate is deposited as a third insulator film on the object surface, and then the third insulator film 308 is etched to form a silicon oxide film for insulating the selected gate 322, and the semiconductor substrate 300 is formed as a first insulator film 309, as well as a fifth insulator film 329, using a thermal oxidation method. After that, a polysilicon film 310, which is assumed to be a floating gate and a field shielding transistor gate, is deposited on the object surface (FIG. 31).

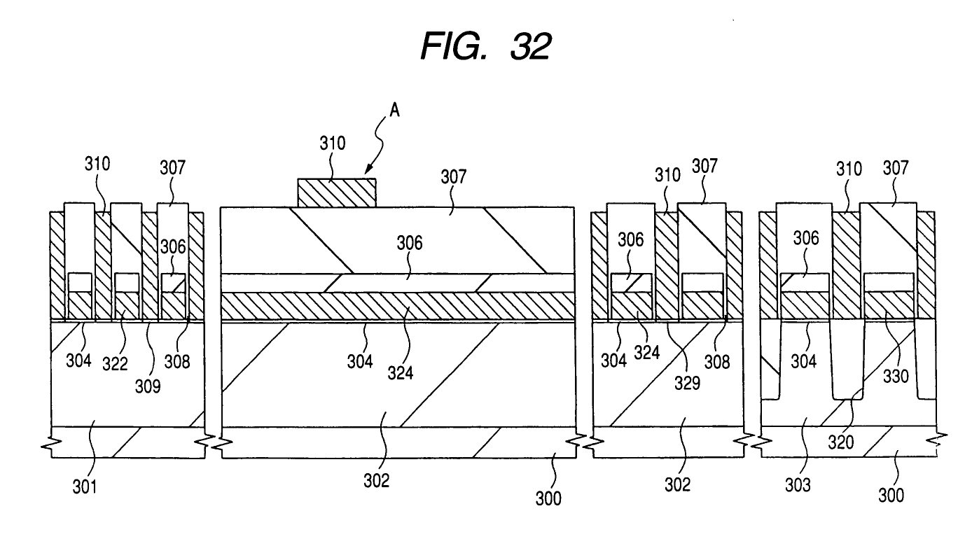

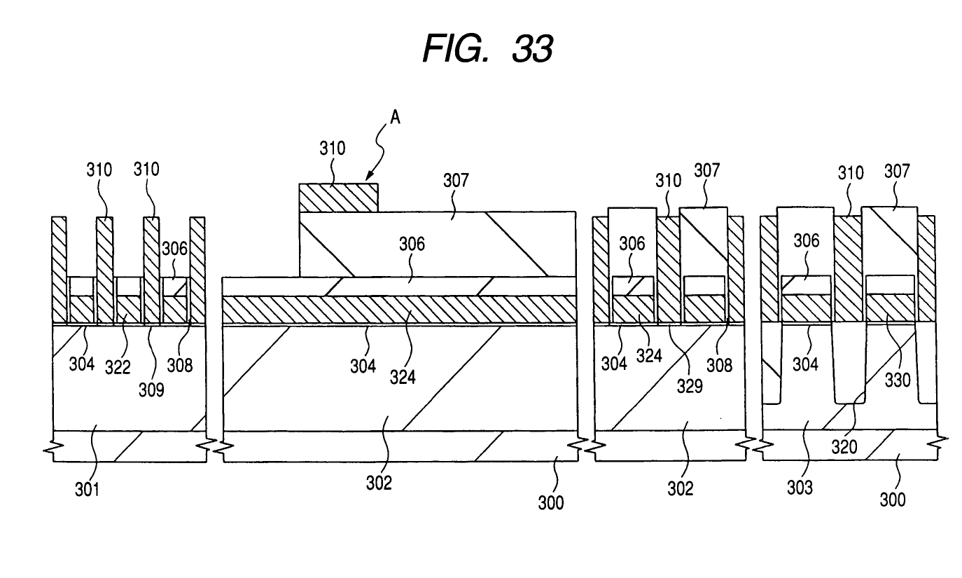

After that, the polysilicon film 310 (FIG. 32A) is etched (FIG. 32) using both lithography and etching techniques, while part of the film 30, to be used as a field shielding transistor gate connector later, is left over. Then, the silicon oxide film 307 located closer to the field shielding transistor gate connector than the memory cell is etched (FIG. 33). After that, the flash memory is completed using the same manufacturing method as that used in the first embodiment.

Therefore, just like the first embodiment, this second embodiment can provide a flash memory at a high production yield, even when the memory cells are disposed in a highly integrated manner by narrowing the bit line pitch.

While preferred forms of the present invention have been described, it is to be understood that modifications will be apparent to those skilled in the art without departing from the spirit of the invention.

The nonvolatile semiconductor memory device of the present invention will thus be employable for memory devices of such compact information devices as portable personal computers, digital still cameras, etc.

1. A nonvolatile semiconductor memory device having:
a plurality of memory cells disposed like a matrix on a semiconductor substrate;
a select transistor having a function to select a row or column direction for said plurality of memory cells disposed like a matrix; and
a peripheral circuit for driving said plurality of memory cells and said select transistor,
wherein said select transistor is isolated from others by a field shielding transistor.

2. The nonvolatile semiconductor memory device according to claim 1,
wherein said plurality of memory cells are isolated respectively by said field shielding transistor.

3. The nonvolatile semiconductor memory device according to claim 1,
wherein some or all of the transistors of said peripheral circuit are isolated from others, respectively by said field shielding transistor.

4. The nonvolatile semiconductor memory device according to claim 1,
wherein the gate of said select transistor is disposed in two steps so as to correspond to each transistor.

5. The nonvolatile semiconductor memory device according to claim 1,
wherein the material of said gate of said field shielding transistor is the same as that of the floating gate of each of said memory cells.

6. The nonvolatile semiconductor memory device according to claim 1,
wherein the gate of said field shielding transistor is connected to that of each of other field shielding transistors.

7. The nonvolatile semiconductor memory device according to claim 6,
wherein a conductive layer made of the same material as that of the first gate of a control gate of each of said memory cells is formed in the upper portion of a gate bundling part of said field shielding transistor.

8. The nonvolatile semiconductor memory device according to claim 1,
wherein each of said memory cells can store information of multiple bits.

9. The nonvolatile semiconductor memory device according to claim 1,
wherein each of said memory cells has a floating gate insulated from said semiconductor substrate by a first insulator film provided therebetween, a control gate formed over said floating gate via a second insulator film, and a select gate formed over said floating gate via a third insulator film provided therebetween.
